(19) United States
(12) Patent Application Publication
(10) Pub. No.: US 2013/0141844 A1
(43) Pub. Date: Jun. 6, 2013

(54) HANDHELD ELECTRONIC DEVICE

(71) Applicants: Meng-Sheng Chiang, Taoyuan County (TW); Yi-Shen Wang, Taoyuan County (TW); Hsiao-Chuan Huang, Taoyuan County (TW); Yi-Bin Ho, Taoyuan County (TW)

(72) Inventors: Meng-Sheng Chiang, Taoyuan County (TW); Yi-Shen Wang, Taoyuan County (TW); Hsiao-Chuan Huang, Taoyuan County (TW); Yi-Bin Ho, Taoyuan County (TW)

(73) Assignee: HTC CORPORATION, Taoyuan County (TW)

(21) Appl. No.: 13/308,567

(22) Filed: Dec. 1, 2011

(51) Int. Cl. H05K 7/00; H01H 13/86

(52) U.S. Cl. 361/679.01; 200/5 A

(57) ABSTRACT

A handheld electronic device including a body and a QWERTY key layout is provided. The body has a case. The QWERTY key layout has a plurality of keys disposed on the case, wherein a fillet is disposed on a corner of each key, and there is a distance of the case between any two adjacent the keys. All the keys are adapted to users to press with their left or right thumb in single hand or both hands while using the handheld electronic device, and a heat conductivity of one of the keys is different from a heat conductivity of another one of the keys.

### BACKGROUND OF THE DISCLOSURE

1. Technical Field

The application relates to a handheld electronic device. More particularly, the application relates to a handheld electronic device having a QWERTY keyboard.

2. Background

A handheld electronic device refers to an electronic device which may be held and operated in a user's hand, such as mobile phone, multimedia player, personal digital assistant (PDA), pocket PC, handheld game console, and handheld global positioning system (GPS). These electronic devices usually have small dimensions and light weight, so that they may be carried around with ease. Some handheld electronic devices (such as mobile phones) further include a QWERTY keyboard, used to improve the input speed of information. The keys of a QWERTY keyboard usually have similar dimensions (i.e. area or height), which increases the chance of accidental contact. Accidental contact means that the finger of the user presses two or more keys at the same time.

### SUMMARY

The disclosure provides a handheld electronic device, adapted to increase the accuracy of information input.

The disclosure provides a handheld electronic device including a body and a QWERTY key layout. The body has a case. The QWERTY key layout has a plurality of keys disposed on the case, wherein a fillet is disposed on a corner of each key, and there is a distance of the case between any two adjacent keys. The keys are adapted to receive a pressure from a left thumb or a right thumb of a user while using the handheld electronic device with a single hand or both hands, and a heat conductivity of one of the keys is different from a heat conductivity of another one of the keys.

Based on the above, the disclosure provides different heat conductivity through the design of the keys. This way, when the user touches a key, the identification toward that key is increased. Thus, the chance of accidental contact is reduced, and the accuracy of information input is increased.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view illustrating a handheld electronic device according to an embodiment of the disclosure.

FIG. 2 is a partial enlarged view of the QWERTY key layout in region A of FIG. 1.

FIG. 3 is a partial enlarged view of the QWERTY key layout in region A of FIG. 1 according to another embodiment of the disclosure.

FIG. 4A is a schematic view illustrating a handheld electronic device according to another embodiment of the disclosure.

FIG. 4B is a partial enlarged view of the QWERTY key layout of FIG. 4A.

FIG. 5 is a partial enlarged view of the QWERTY key layout according to yet another embodiment of the disclosure.

FIG. 6 is a partial enlarged view of the QWERTY key layout according to yet another embodiment of the disclosure.

### DETAILED DESCRIPTION

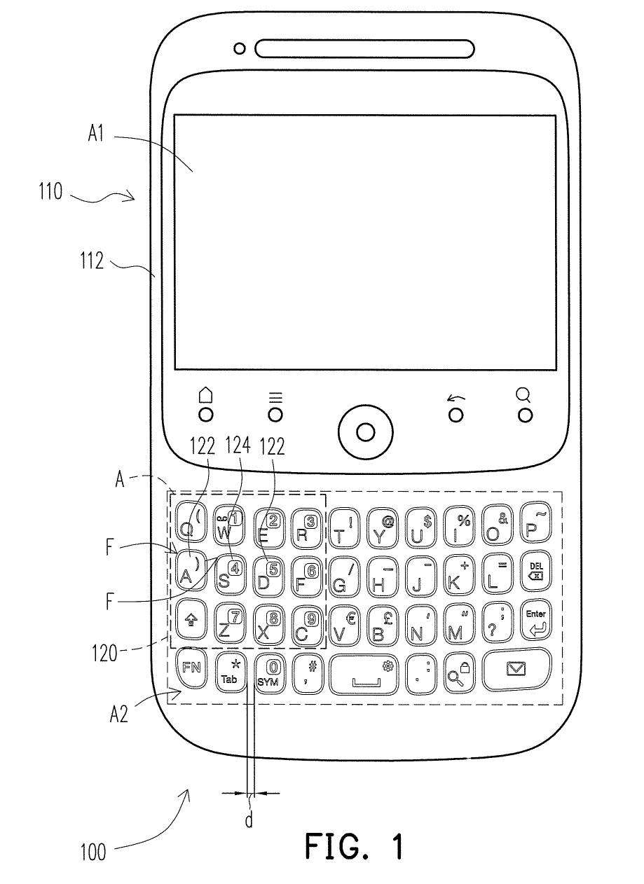

FIG. 1 is a schematic view illustrating a handheld electronic device according to an embodiment of the disclosure. Referring to FIG. 1, in the embodiment, the handheld electronic device 100 is, for example, a mobile phone. The handheld electronic device 100 includes a body 110 and a QWERTY key layout 120. The body 110 includes a case 112, and the body 110 includes a display area A1 and a key area A2 adjacent to the display area A1. The QWERTY key layout 120 is located in the key area A2. The QWERTY key layout 120 has a plurality of keys 122, 124 disposed on the case 112. The keys 122, 124 are arranged in the key area A2, wherein a fillet F is disposed on a corner of the key 122 and the key 124, and there is a distance d of the case 112 between any two adjacent keys 122, 124. The keys 122, 124 are adapted to receive a pressure from a left thumb or a right thumb of a user while using the handheld electronic device 110 with a single hand or both hands. A heat conductivity of one of the keys 122 is different from a heat conductivity of another one of the keys 124. Thus, when the user touches the key 122 or the key 124, because the tactile impression of the key 122 is different from the tactile impression of the key 124, the identification toward the keys 122, 124 is increased. Thus, the chance of accidental contact of the keys 122, 124 is reduced, and the accuracy of information input is increased. At the same time, the fillet F is disposed on a corner of each of the keys 122, 124, and there is the distance d between the key 122 and the key 124. This way, the finger may more accurately touch the key 122 or the key 124, so as to reduce the chance of accidental contact towards the keys 122, 124.

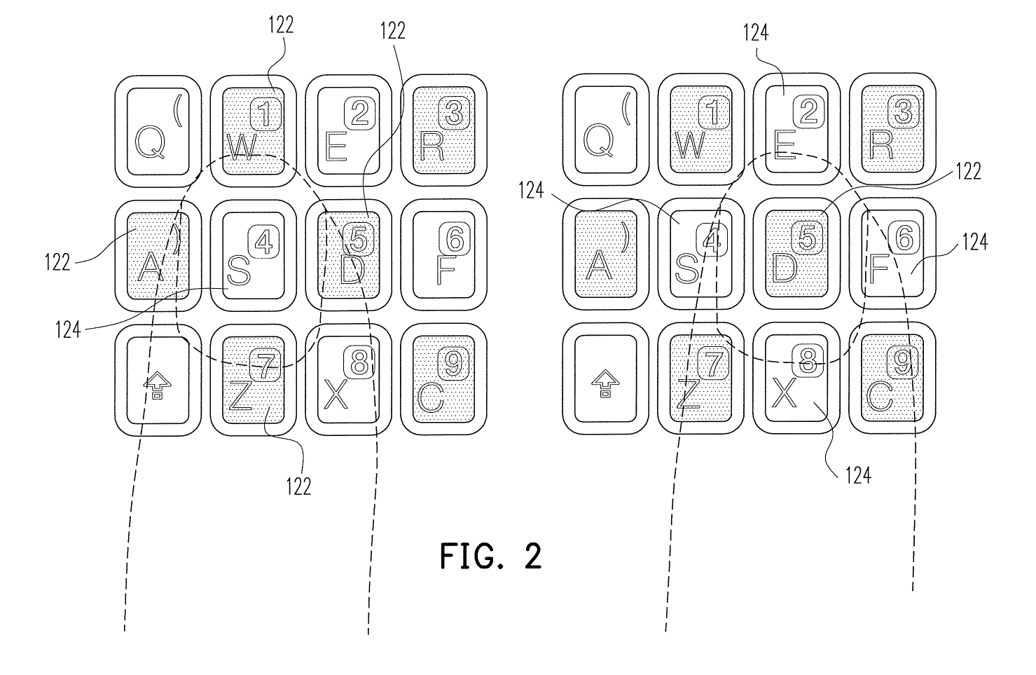

FIG. 2 is a partial enlarged view of the QWERTY key layout in region A of FIG. 1. Referring to FIG. 2, a material of the key 122 of the embodiment includes a first thermal conductivity coefficient, and a material of the key 124 includes a second thermal conductivity coefficient. The first thermal conductivity coefficient is different from the second thermal conductivity coefficient. In addition, a material of the key 122 is one of plastic, metal, or rubber, and a material of the key 124 is another one of plastic, metal, or rubber. For example, if the material of the key 122 is plastic, then the material of the key 124 is metal. This is because the keys 124 are disposed around the key 122, and the heat conductivity of metal is faster than the heat conductivity of plastic. Thus, when the finger of the user contacts the key 124 in the left hand picture of FIG. 2, the user will feel a colder tactile impression. In addition, when the finger of the user moves to contact the key 122 in the right hand picture of FIG. 2, since plastic has a slower heat conductivity than metal, the user will feel a warmer tactile impression. Thus, the keys 122, 124 having different materials with different heat conductivity will improve the identification of the keys 122, 124, and reduce the chance of accidental contact towards the keys 122, 124.

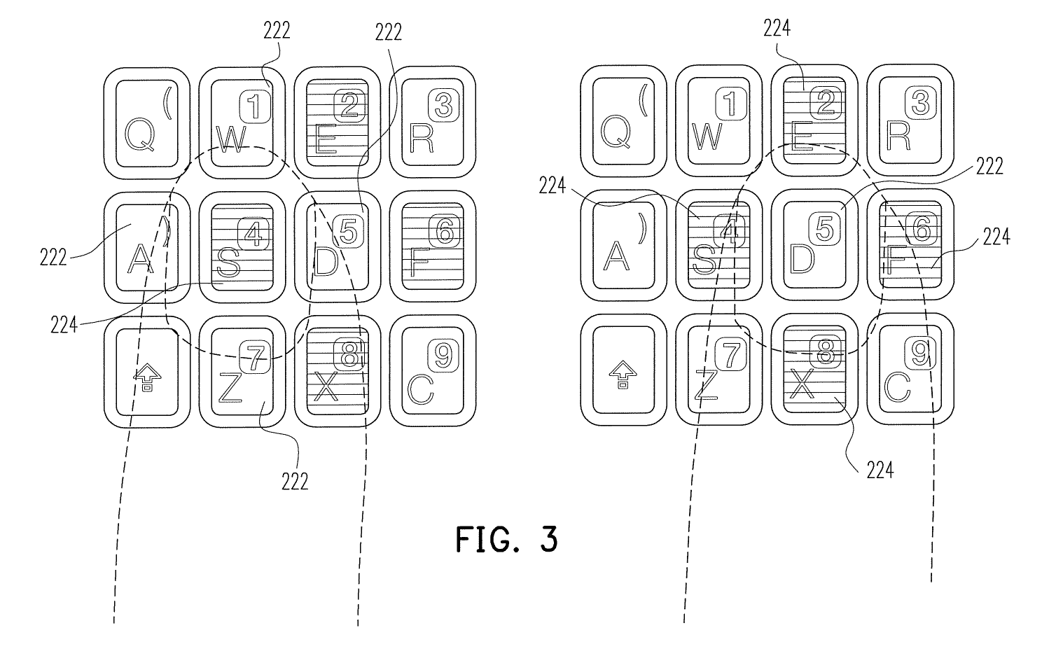

FIG. 3 is a partial enlarged view of the QWERTY key layout in region A of FIG. 1 according to another embodiment of the disclosure. Referring to FIG. 3, in the embodiment, the surface of the key 222 is smoother, and the surface of the key 224 is rougher. In other words, the key 222 has a smooth surface, for example a glossy surface, and the key 224 has a rough surface, for example a matt surface. After the finger of the user presses the key 224 in the left hand side of FIG. 3 or the key 222 in the right hand side of FIG. 3, because the surface of the key 222 is smoother than the surface of the key 224, the heat conductivity of the key 222 is different from the heat conductivity of the key 224. Thus, the keys 222, 224 having different surfaces with different heat conductivity will improve the identification of the keys 222, 224, and reduce the chance of accidental contact towards the keys 222, 224. It should be noted that the embodiments describing the keys with different heat conductivity are only exemplary. The user may use keys with different materials, keys with different surfaces, or a combination of different materials and different surfaces, so as to have keys with different heat conductivity.

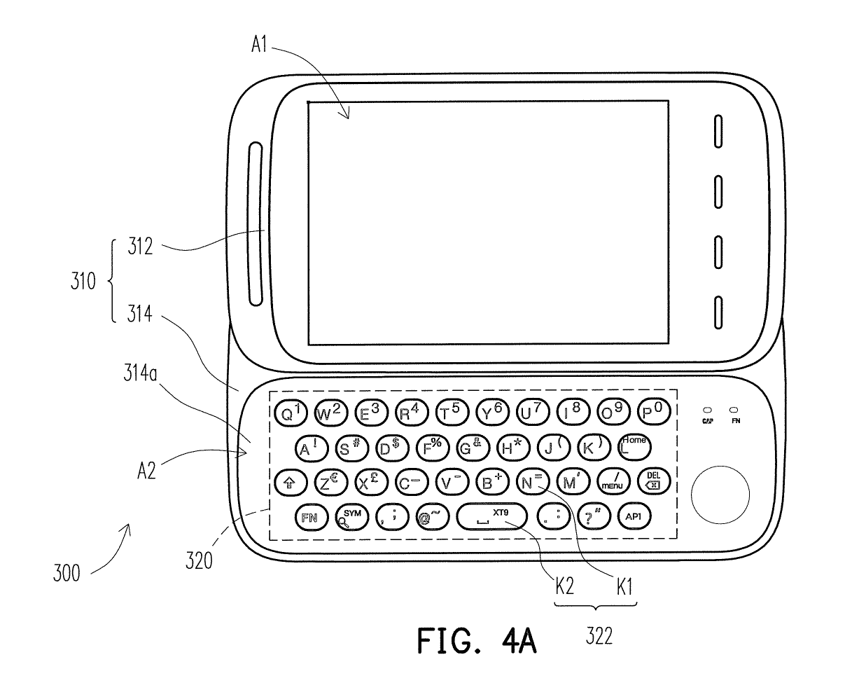

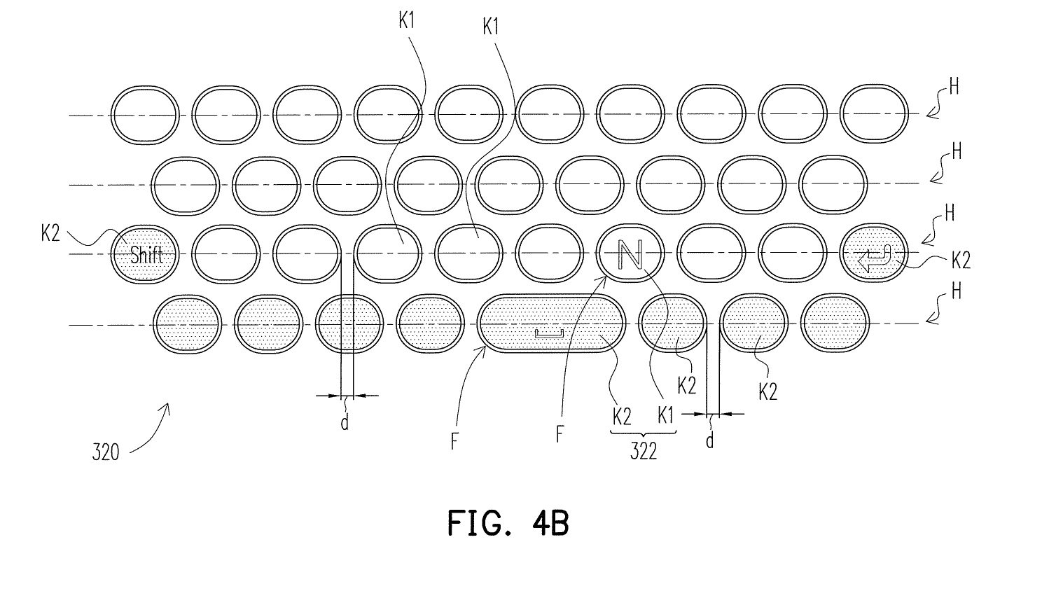

FIG. 4A is a schematic view illustrating a handheld electronic device according to another embodiment of the disclosure. FIG. 4B is a partial enlarged view of the QWERTY key layout of FIG. 4A. Referring to FIG. 4A and FIG. 4B, in the embodiment, a handheld electronic device 300 includes a body 310 and a QWERTY key layout 320. The body 310 includes a first sub-body 312 and a second sub-body 314. The first sub-body 312 is movably connected to the second sub-body 314, so as to be expanded or retracted relative to the second sub-body 314. The first sub-body 312 includes display area A1. The second sub-body 314 includes a key area A2. The QWERTY key layout 320 is located in the key area A2. When the second sub-body 314 is expanded relative to the first sub-body 312, the key area A2 is adjacent to the display area A1. In contrast to the bar-type handheld electronic device 100 of FIG. 1, the handheld electronic device 300 of the embodiment adopts a slide-type design.

The QWERTY key layout 320 of the embodiment includes a plurality of keys 322, disposed in a case 314a of the second sub-body 314. The keys 322 are arranged in the key area A2, wherein the keys 322 include a plurality of character keys K1, arranged in rows H, and a plurality of function keys K2, arranged in rows H. In addition, a corner of each of the character keys K1 and the function keys K2 respectively have a fillet F, and there is a distance d by the case 314a respectively between any two adjacent character keys K1 and between any two adjacent function keys K2. The heat conductivity of the character keys K1 is different from the heat conductivity of the function keys K2. For example, when the user presses the function key K2 (for example the “space” key), or presses the character key K1 (for example the “N” key), the keys with different materials or different surfaces described in the previous embodiment may be applied so that the heat conductivity of the key K1 is different from the heat conductivity of the key K2. Therefore, the chance of accidental contact in the keys 322 is reduced. The following is a description directed towards special keys or keys in different locations having different heat conductivity.

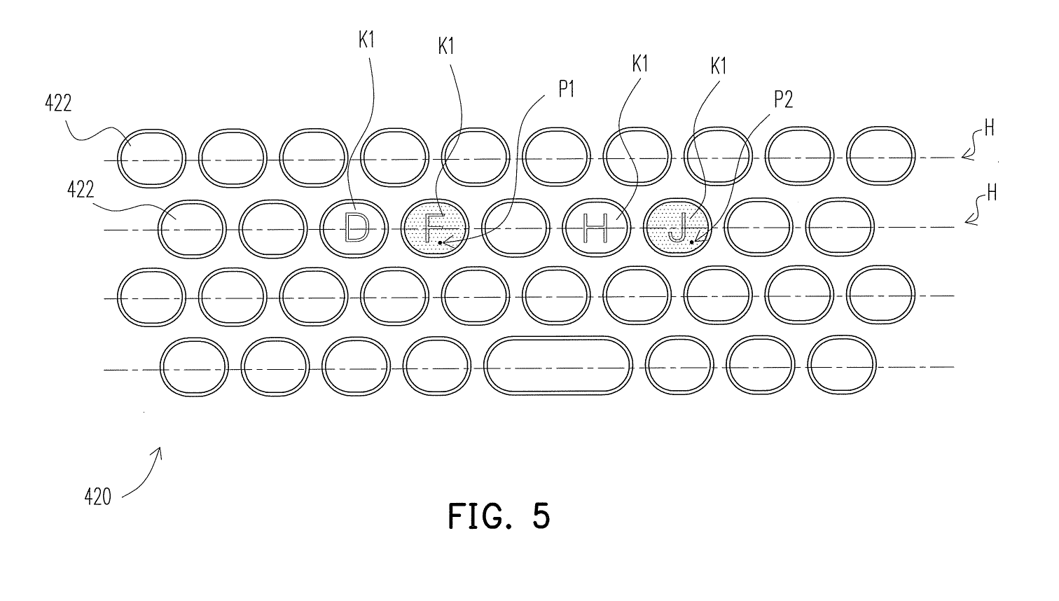

FIG. 5 is a partial enlarged view of the QWERTY key layout according to yet another embodiment of the disclosure. Referring to FIG. 5, keys 422 of a QWERTY key layout 420 of the embodiment are arranged in a plurality of rows H. These keys 422 include a plurality of character keys K2, and the heat conductivity of the character keys K1 (for example the “F” key and the “J” key) which include a raised dot P1 is different from the heat conductivity of the character keys K1 (for example the “D” key and the “H” key) that do not have a raised dot P1. Thus, if the user is blind, besides the assistance of keys with raised dots, the keys having different heat conductivity may also improve the identification of the keys 422, thereby reducing the chance of accidental contact towards the keys 422.

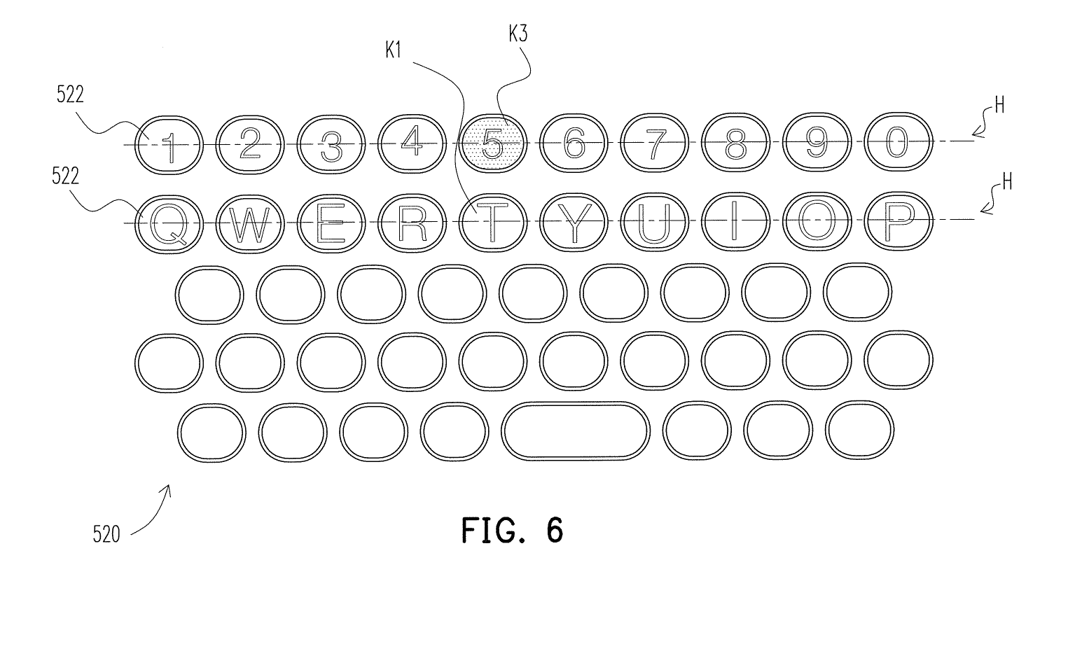

FIG. 6 is a partial enlarged view of the QWERTY key layout according to yet another embodiment of the disclosure. Referring to FIG. 6, keys 520 of a QWERTY key layout 522 of the embodiment are arranged in a plurality of rows H. The keys 522 include a plurality of character keys K1 and a plurality of number keys K3. A single row H of the number keys K3 are arranged above the character keys K1, and the heat conductivity of the number keys K3 is different from the heat conductivity of the character keys K1. Thus, when the character keys K1 do not include the number keys K3 at the same time, the identification between the character keys K1 and the number keys K3 is raised, so as to reduce the chance of accidental contact towards the keys 522.

To sum up, in the disclosure, a heat conductivity of the keys is different from another heat conductivity of the keys. Thus, the tactile impression in identifying different keys is raised, so as to reduce the chance of accidental contact. At the same time, the corner of each key includes a fillet, and there is a distance of the case between any two adjacent keys, so that the finger of the user may more accurately touch a key. In addition, when two keys have different materials, different surfaces, or a combination of the two, the two keys will have two different heat conductivity.

It will be apparent to those skilled in the art that various modifications and variations may be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A handheld electronic device, comprising:
a body, having a case; and
a QWERTY key layout, having a plurality of keys disposed on the case, wherein a fillet is disposed on a corner of each key, and there is a distance of the case between any two adjacent keys, the keys are adapted to receive a pressure from a left thumb or a right thumb of a user while using the handheld electronic device with a single hand or both hands, and a heat conductivity of one of the keys is different from a heat conductivity of another one of the keys.

2. The handheld electronic device as claimed in claim 1, wherein a material of the keys includes a first thermal conductivity coefficient, and another material of the keys includes a second thermal conductivity coefficient, and the first thermal conductivity coefficient is different from the second thermal conductivity coefficient.

3. The handheld electronic device as claimed in claim 1, wherein a material of the keys is one of plastic, metal, or rubber, and another material of the keys is another one of plastic, metal, or rubber.

4. The handheld electronic device as claimed in claim 1, wherein a surface of the keys is smoother, and another surface of the keys is rougher.

5. The handheld electronic device as claimed in claim 1, wherein the body has a display area and a key area adjacent to the display area, and the keys are arranged in the key area.

6. The handheld electronic device as claimed in claim 1, wherein the body includes a first sub-body and a second sub-body, the first sub-body is movably connected to the second sub-body, so as to be expanded or retracted relative to the second sub-body, and the first sub-body includes a display area, the second sub-body includes a key area, and the keys are arranged in the key area, and when the second sub-body is expanded with respect to the first sub-body, the key area is adjacent to the display area.

7. The handheld electronic device as claimed in claim 1, wherein the keys include a plurality of character keys and a plurality of function keys, and a heat conductivity of the character keys is different from a heat conductivity of the function keys.

8. The handheld electronic device as claimed in claim 1, wherein the keys are arranged in a plurality of rows, the keys include a plurality of character keys and a plurality of number keys, the number keys are arranged in a single row above the character keys, and a heat conductivity of the character keys is different from a heat conductivity of the number keys.

9. The handheld electronic device as claimed in claim 1, wherein the keys are arranged in a plurality of rows, and the keys include a plurality of character keys, and a heat conductivity of the character keys including a raised dot is different from a heat conductivity of the character keys without a raised dot.
